(19) United States
(12) Patent Application Publication
(10) Pub. No.: US 2026/0114314 A1
(43) Pub. Date: Apr. 23, 2026

(54) UNIVERSAL STRUCTURE FOR ACHIEVING A 360-DEGREE SPATIAL LIGHT EMISSION IN A WHITE OR MONOCHROMATIC LIGHT LED

(71) Applicant: Shenzhen Guangshe Zhaoming Technology Co., LTD, Shenzhen (CN)

(72) Inventor: JianWei CHEN, Shenzhen (CN)

(21) Appl. No.: 18/934,104

(22) Filed: Oct. 31, 2024

(30) Foreign Application Priority Data
Oct. 18, 2024 (CN) 202411464469.0

(51) Int. Cl. H01L 23/31; H01L 23/00; H01L 23/29

(52) U.S. Cl. CPC H10W 74/111; H10W 74/40; H10W 72/884; H10W 90/736; H10W 90/756

(57) ABSTRACT

A universal structure for achieving a 360-degree spatial light emission in a white or monochromatic light LED, including: an LED direct insertion holder, an LED chip, wires, and chip bonding material, LED concapsulation gel, chip forming gel, an auxiliary material, the chip bonding material is placed on a solid crystal position of the LED direct insertion holder, the LED chip is fixedly connected to the LED direct insertion holder through the chip bonding material, the LED chip is electrically connected to the LED direct insertion holder via the wire; the chip forming gel is applied at the solid crystal position of the LED direct insertion holder, an LED reflective cup or a flat cup structure is provided inside the LED direct insertion holder. This disclosure addresses the issues of the existing LED concapsulation structure lacking versatility, having a complex concapsulation process, and producing low light quality levels.

### CROSS-REFERENCE TO RELATED APPLICATIONS

This application claims foreign priority of Chinese Patent Application No. 202411464469.0, filed on Oct. 18, 2024 in the China National Intellectual Property Administration, the disclosures of all of which are hereby incorporated by reference.

### TECHNICAL FIELD

The present disclosure relates to the technical field of LED concapsulation technology, in particular to a universal structure for achieving a 360-degree spatial light emission in a white or monochromatic light LED.

### BACKGROUND

The so-called 360-degree light emitting diode (LED), fully referred to as the 360-degree spatial light-emitting LED, is also known as the all-around light LED, which is refers to as 360-degree LED or 360-degree spatial light-emitting LED.

Since its birth, the solution for achieving 360-degree spatial light emission with white light and monochromatic light in 360-degree LED has mainly been realized through a direct insertion holder with a flat cup LED combined with the addition of auxiliary materials in the LED concapsulation gel. Monochromatic light primarily adds diffusing materia, while white light mainly incorporates phosphor as well as diffusing material and diffusing powders.

Based on the existing solutions mentioned above, we can identify two typical structural features: first, the LED direct insertion holder does not have a reflective cup; second, auxiliary material (including diffusing agent/powder or phosphor, etc.) is added within the optical cavity of the LED concapsulation gel. According to these typical structural features, the manufacturing process is characterized by either single concapsulation or secondary concapsulation, with secondary concapsulation technology being mainly adopted to achieve better light uniformity.

For example, typical patents for secondary concapsulation are as following: “360-degree (volume emitting) high-efficiency photoluminescent diode”, Chinese patent No. is CN2004100524874; “adaptive 360-degree volume emitting white light diode”, Chinese patent No. is CN2005100346782.

For typical patents of single concapsulation are as following:

“360-degree volume emitting diode,” Chinese patent No. is CN200520064262.0 (note: typical single concapsulation white light); “360-degree white light emitting diode,” Chinese Patent No. is CN200720120245.3″ (note: typical single concapsulation white light).

Comparing the four Chinese patents above, they share the common feature that the LED direct insertion holders do not have reflective cups. Additionally, the concapsulation methods involve either single concapsulation or secondary concapsulation. These two commonalities indicate that using LED direct insertion holders without reflective cups aims to achieve a larger emission angle, while the common goal of implementing either single or secondary concapsulation is to create a larger optical cavity or multilayer optical cavity through the LED concapsulation gel, thereby achieving 360-degree spatial light emission with direct insertion LED.

The followed are drawbacks of the above concapsulation methods.

Lack of universality: achieving 360-degree spatial light emission with LED can only be accomplished using flat cup LED direct insertion holders.

Complex concapsulation process: to achieve optimal light quality, this is primarily realized through secondary concapsulation, which significantly increase production costs.

Low light quality: this is mainly manifested in the presence of a “three-segment light” flaw. The “three-segment light” phenomenon refers to the uneven lighting that occurs in direct insertion LED components when the concapsulation diameter is ≤Φ5 mm, especially when the height of the package is >5 mm. This results in three uneven light zones: yellow, bright, and brighter. We refer to this occurrence as the “three-segment light” phenomenon. When measuring this phenomenon in terms of “light quality,” it indicates light non-uniformity. In smaller concapsulation sizes, the “three-segment light” flaw has yet to be adequately resolved. Therefore, we propose a universal structure for white and monochromatic LED to achieve 360-degree spatial light emission.

### SUMMARY

The present disclosure provides a universal structure for achieving a 360-degree spatial light emission in a white or monochromatic light LED, to solve the technical problem that the existing LED concapsulation structure lacking versatility, having a complex concapsulation process, and producing low light quality levels as mentioned in the background technology.

To realize the above objective, the present disclosure provides a universal structure for achieving a 360-degree spatial light emission in a white or monochromatic light light emitting diode (LED), including an LED direct insertion holder, an LED chip, and wires, and chip bonding material, and LED concapsulation gel, and chip forming gel, and an auxiliary material, wherein the chip bonding material is placed on a solid crystal position of the LED direct insertion holder, the LED chip is fixedly connected to the LED direct insertion holder through the chip bonding material, and the LED chip is electrically connected to the LED direct insertion holder via one of the wires; and the chip forming gel is applied at the solid crystal position of the LED direct insertion holder, an LED reflective cup or a flat cup structure is provided inside the LED direct insertion holder; and the chip forming gel completely covers the LED chip and has a certain height in a shape of a light center-like spherical cap, a semi-spherical, or an elliptical body; and an exterior of the LED direct insertion holder is encapsulated with the LED concapsulation gel.

Furthermore, the chip forming gel applied to the LED direct insertion holder, which contains the LED reflective cup, extends along the LED reflective cup and has a certain height in the shape of the light center-like spherical cap, the semi-spherical, or the elliptical body.

Furthermore, the chip bonding material is a conductive or non-conductive bonding material.

Furthermore, the chip forming gel is made by silicone or modified silicone.

Furthermore, the chip forming gel contains the auxiliary material, and the auxiliary material is a diffusion material, which is a diffuser or diffusion powders.

Furthermore, the chip forming gel contains the auxiliary material, and the auxiliary material is a fluorescent material, which is phosphor.

Furthermore, the LED concapsulation gel is in a standard shape, a non-standard shape, a circular shape, or a flat-top shape.

Furthermore, when a top of the LED concapsulation gel is flat, the LED concapsulation gel is transparent, or it contains the diffusion material to form a translucent body.

Compared to the prior arts, the beneficial effects of the present disclosure are as follow: the disclosure achieves 360-degree spatial light emission within the direct-insert LED by using adhesive to form chip gel that has a “certain height with a high light center resembling a spherical cap, semi-spherical, or elliptical body.” Furthermore, it breaks the convention that 360-degree spatial light emission can only be achieved with flat cup LED direct insertion holders. The disclosure meets three criteria for light quality. Additionally, the design featuring a certain height with a high light center significantly simplifies the concapsulation process for 360-degree LED, while also reducing or eliminating the “three-segment light” defect, thus ensuring uniform light distribution. This resolves the issues of existing LED concapsulation structures lacking versatility, having complex concapsulation processes, and producing low light quality levels.

### BRIEF DESCRIPTION OF THE DRAWINGS

FIG. 1 is a schematic structural diagram of a monochromatic light LED according to an embodiment of the present disclosure.

FIG. 2 is a schematic structural diagram of a chip forming gel of the monochromatic light LED with a shape of elliptical body according to an embodiment of the present disclosure.

FIG. 3 is a schematic structural diagram of a white light LED with a reflective cup according to an embodiment of the present disclosure.

FIG. 4 is a schematic structural diagram of a white light LED with a flat cup according to an embodiment of the present disclosure.

FIG. 5 is a schematic structural diagram of a traditional directional light-emitting direct insertion LED.

FIG. 6 is a schematic structural diagram of a 360-degree monochromatic light LED according to an embodiment of the present disclosure.

FIG. 7 is a schematic structural diagram of a 360-degree white light LED with phosphor encapsulated outerside according to an embodiment of the present disclosure.

FIG. 8 is a schematic structural diagram of a 360-degree white light LED with phosphor encapsulated inside according to an embodiment of the present disclosure.

### LABELS AND DESCRIPTION

1 LED direct insertion holder, 2 LED chip, 3 wire, 4 chip bonding material, 5 LED concapsulation gel, 6 LED reflective cup, 7 fluorescent material, 8 LED internal concapsulation gel, 9 diffusion material, 10 chip forming gel.

### DETAILED DESCRIPTION OF THE EMBODIMENTS

The following will provide a clear and complete description of the technical solutions in the embodiments of the present invention in conjunction with the accompanying drawings. It is evident that the described embodiments are only a portion of the various embodiments of the present disclosure, and not all possible embodiments.

### A First Embodiment

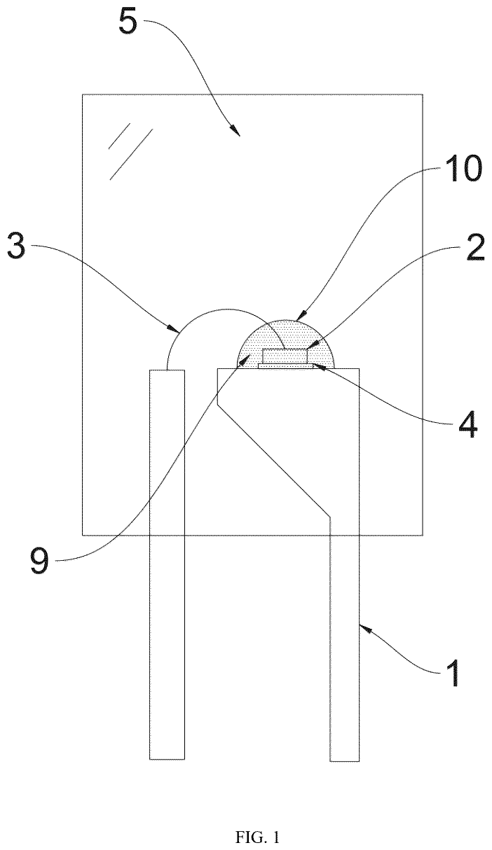

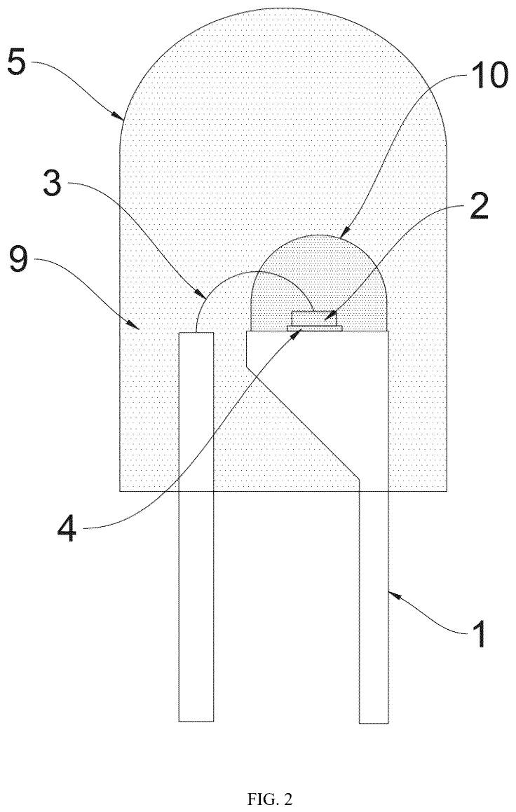

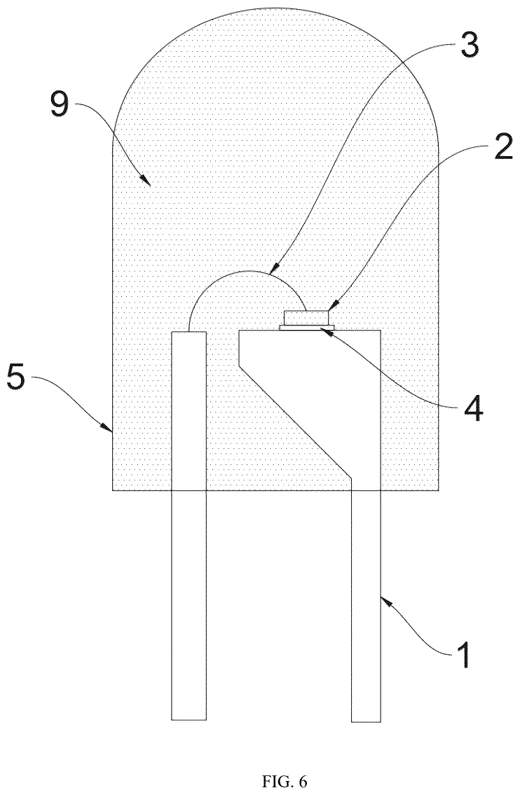

Please refers to FIGS. 1-2 and 6, for a universal structure for achieving a 360-degree spatial light emission in a monochromatic light, a chip bonding material (4) is placed on a solid crystal position of a LED direct insertion holder (1). A LED chip (2) is fixedly connected to the LED direct insertion holder (1) through the chip bonding material (4). The LED chip (2) is electrically connected to the LED direct insertion holder (1) via one of wires (3). And chip forming gel (10) is applied at the solid crystal position of the LED direct insertion holder (1), an LED reflective cup (6) or a flat cup structure is provided inside the LED direct insertion holder (1). The chip forming gel (10) completely covers the LED chip (2) and has a certain height in a shape of a light center-like spherical cap, a semi-spherical, or an elliptical body; and an exterior of the LED direct insertion holder (1) is encapsulated with LED concapsulation gel (5).

In the first embodiment, a slight modification can be made in a LED concapsulation gel process by adding a diffusion material (9) to the LED concapsulation gel 5, resulting in a translucent LED concapsulation gel 5 with diffusion properties.

In this embodiment, the top of the LED concapsulation gel (5) is flat or nearly flat, and not only suit for monochromatic light but also suit for white light LED packing.

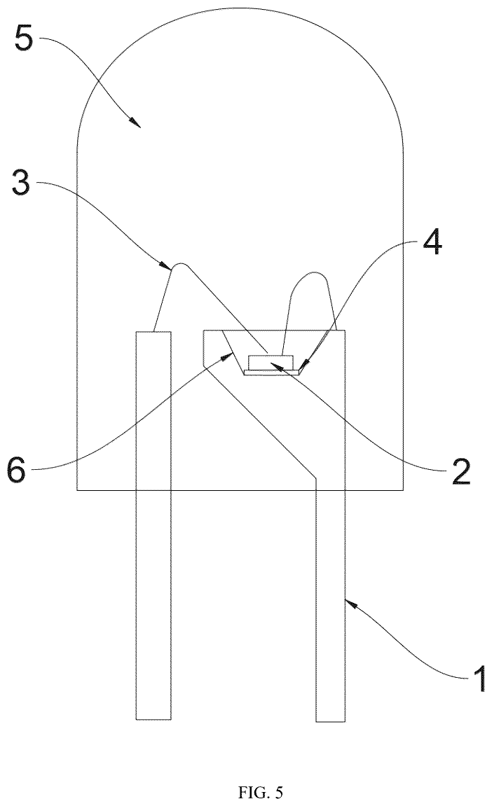

Comparing with a traditional directional light-emitting direct insertion LED shown in FIG. 5, the universal structure for achieving the 360-degree spatial light emission in the monochromatic light can achieve 360-degree spatial light emission.

### A Second Embodiment

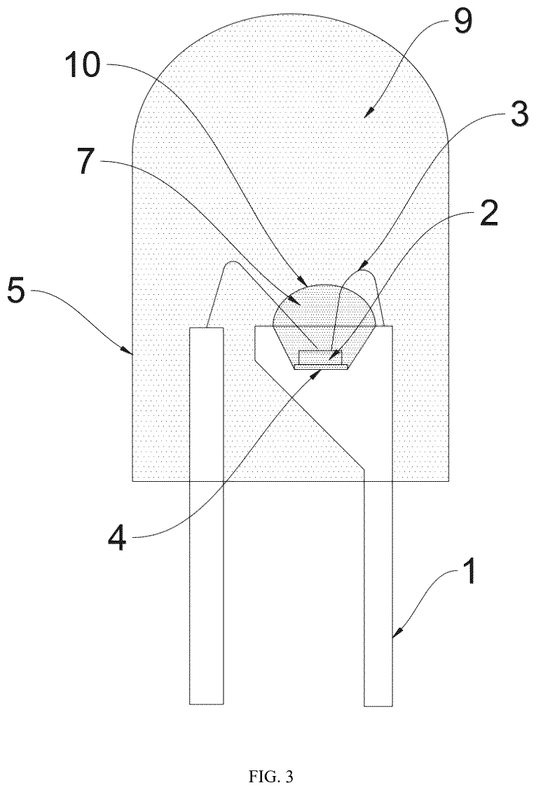

Please refers to FIG. 3, FIG. 3 shows a universal structure for achieving a 360-degree spatial light emission in a white light LED, a chip bonding material (4) is placed on a solid crystal position of a LED direct insertion holder (1). A LED chip (2) is fixedly connected to the LED direct insertion holder (1) through the chip bonding material (4). The LED chip (2) is electrically connected to the LED direct insertion holder (1) via one of wires (3). And then, adhesive is applied to the LED chip 2 and the LED reflector cup 6 to form the chip forming gel 10. The chip forming gel 10 uses a modified silicone with high thixotropy and contains fluorescent material 7, diffusion material 9 can also be mixed in. The chip forming gel 10 creates a shape resembling a spherical cap, semi-sphere, or elliptical body with a certain height and high light center. The component is then encapsulated using the LED concapsulation gel 5, which includes diffusion materia 9.

### A Third Embodiment

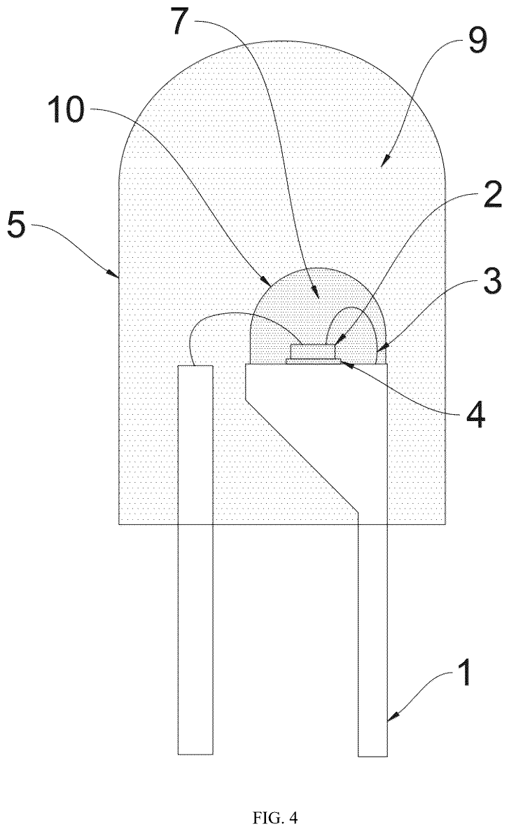

Please refers to FIG. 4, FIG. 4 shows a universal structure for achieving a 360-degree spatial light emission in a white light LED, a chip bonding material (4) is placed on a solid crystal position of a LED direct insertion holder (1) without a LED reflective cup (6). A LED chip (2) is fixedly connected to the LED direct insertion holder (1) through the chip bonding material (4). The LED chip (2) is electrically connected to the LED direct insertion holder (1) via one of wires (3). And then, adhesive is applied to the LED chip 2 and the LED reflector cup 6 to form the chip forming gel 10. The chip forming gel 10 uses a modified silicone with high thixotropy and contains fluorescent material (7), diffusion materials (9) can also be mixed in. The chip forming gel 10 creates a shape resembling a spherical cap, semi-sphere, or elliptical body with a certain height and high light center. The component is then encapsulated using the LED concapsulation gel 5, which includes diffusion material 9.

In the above embodiments, the newly designed basic solution for white light can be used not only for packing with diameters ≤Φ5 mm, but also for Φ 12 mm packing, as well as for longer packing bodies (e.g., DX-326 light strips), while meeting the optical quality criteria.

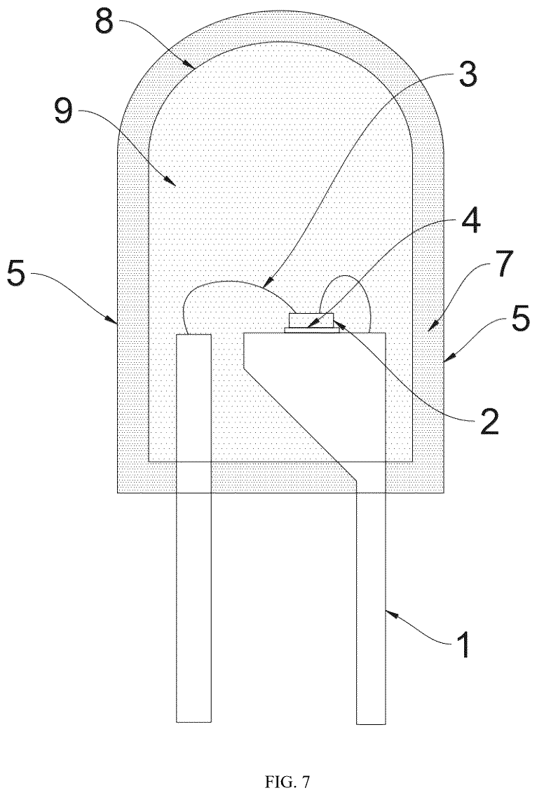

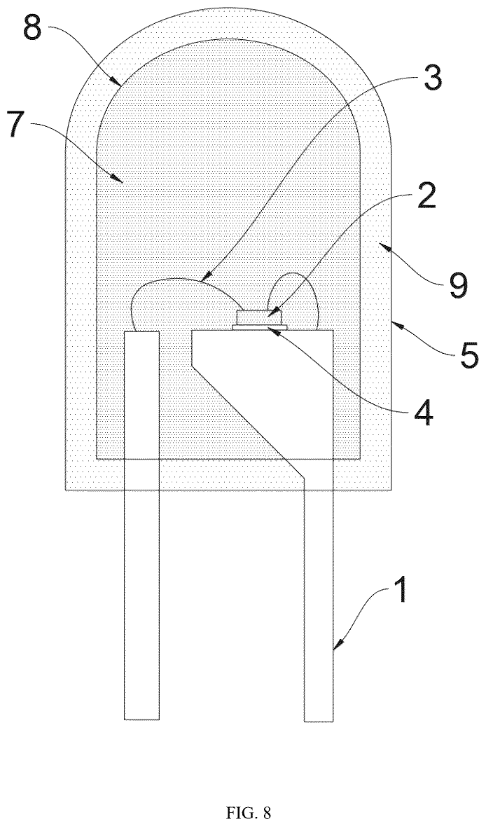

Furthermore, the white light LED shown in FIGS. 7-8 include LED internal concapsulation gel 8 between the fluorescent material 7 and the diffusion material 9, to improve the ability of 360-degree spatial light emission.

### CONCLUSION

Whether for flat cups or cup-shaped reflectors, whether for long or short packing bodies, whether for large or small sizes, and whether for standard geometric or non-standard packing, 360-degree spatial illumination can be achieved, fulfilling the requirements for optical quality. The preferred optimization angle is the flat cup, with transparent packing limited to those with flat tops. Under the same scale conditions, the K value of the transparent packing is less than that of the packing with added diffusion agents.

The flat cup design reduces the unevenness of the “three-segment light” phenomenon in white light LEDs. (Note: This phenomenon is particularly prominent in smaller sizes, i.e., ≤Φ5 mm.)

For those skilled in the art, it is clear that the invention is not limited to the details of the exemplary embodiments described above, and that it can be realized in other specific forms without departing from the spirit or essential characteristics of the disclosure. Therefore, the embodiments should be regarded as illustrative and non-restrictive. The scope of the disclosure is defined by the appended claims, not by the above description, and all variations that fall within the meaning and scope of the claims are intended to be encompassed by the disclosure. No reference signs in the claims should be construed as limiting the claims themselves.

What is claimed is:

1. A universal structure for achieving a 360-degree spatial light emission in a white or monochromatic light light emitting diode (LED), comprising an LED direct insertion holder (1), an LED chip (2), and wires (3), and chip bonding material (4), and LED concapsulation gel (5), and chip forming gel (10), and an auxiliary material;
wherein the chip bonding material (4) is placed on a solid crystal position of the LED direct insertion holder (1), the LED chip (2) is fixedly connected to the LED direct insertion holder (1) through the chip bonding material (4), and the LED chip (2) is electrically connected to the LED direct insertion holder (1) via one of the wires (3); and
the chip forming gel (10) is applied at the solid crystal position of the LED direct insertion holder (1), an LED reflective cup (6) or a flat cup structure is provided inside the LED direct insertion holder (1); and the chip forming gel (10) completely covers the LED chip (2) and has a certain height in a shape of a light center-like spherical cap, a semi-spherical, or an elliptical body; and an exterior of the LED direct insertion holder (1) is encapsulated with the LED concapsulation gel (5).

2. The universal structure for achieving the 360-degree spatial light emission in the white or monochromatic light LED of claim 1, wherein the chip forming gel (10) applied to the LED direct insertion holder (1), which contains the LED reflective cup (6), extends along the LED reflective cup (6) and has a certain height in the shape of the light center-like spherical cap, the semi-spherical, or the elliptical body.

3. The universal structure for achieving the 360-degree spatial light emission in the white or monochromatic light LED of claim 1, wherein the chip bonding material (4) is a conductive or non-conductive bonding material.

4. The universal structure for achieving the 360-degree spatial light emission in the white or monochromatic light LED of claim 1, wherein the chip forming gel (10) is made by silicone or modified silicone.

5. The universal structure for achieving the 360-degree spatial light emission in the white or monochromatic light LED of claim 1, wherein the chip forming gel (10) contains the auxiliary material, and the auxiliary material is a diffusion material (9), which is a diffuser or diffusion powders.

6. The universal structure for achieving the 360-degree spatial light emission in the white or monochromatic light LED of claim 1, wherein the chip forming gel (10) contains the auxiliary material, and the auxiliary material is a fluorescent material (7), which is phosphor.

7. The universal structure for achieving the 360-degree spatial light emission in the white or monochromatic light LED of claim 1, wherein the LED concapsulation gel (5) is in a standard shape, a non-standard shape, a circular shape, or a flat-top shape.

8. The universal structure for achieving the 360-degree spatial light emission in the white or monochromatic light LED of claim 7, wherein when a top of the LED concapsulation gel (5) is flat, the LED concapsulation gel (5) is transparent, or it contains the diffusion material (9) to form a translucent body.
